(19) United States
(12) Patent Application Publication
(10) Pub. No.: US 2025/0105020 A1
(43) Pub. Date: Mar. 27, 2025

(54) PLASMA PROCESSING METHOD

(71) Applicant: Hitachi High-Tech Corporation, Minato-ku, Tokyo (JP)

(72) Inventors: Masaya IMAI, Tokyo (JP); Miyako MATSUI, Tokyo (JP); Takashi SHIOTA, Tokyo (JP); Koichi TAKASAKI, Tokyo (JP); Kenichi KUWAHARA, Tokyo (JP)

(21) Appl. No.: 18/279,797

(22) PCT Filed: Jun. 15, 2022
(86) PCT No.: PCT/JP2022/023881

§ 371 Date: Aug. 31, 2023

(51) Int. Cl. H01L 21/3213; H01L 21/3205

(52) U.S. Cl. CPC H01L 21/32136; H01L 21/32051

(57) ABSTRACT

A plasma processing method for etching a ruthenium film by plasma, including a step of forming and removing a side wall protective film while reducing impurity contamination, and processing a ruthenium pattern into a desired cross-sectional shape. The method includes: a first step of etching the ruthenium film by plasma generated using a mixed gas of an oxygen gas and a halogen gas; a second step of forming a ruthenium compound on a side wall of the etched ruthenium film by radicals generated by plasma generated using the halogen gas, after the first step; a third step of etching the ruthenium film by the plasma generated using the mixed gas, after the second step; and a fourth step of etching the side wall of the etched ruthenium film by oxygen radicals and halogen radicals generated by the plasma generated using the mixed gas, after the third step.

### TECHNICAL FIELD

The present disclosure relates to a plasma etching processing method, and more particularly, to a plasma processing method including a step of precisely controlling a pattern shape of a ruthenium pattern film.

### BACKGROUND ART

Application of ruthenium as a wiring metal is being studied with miniaturization and three-dimensional formation of a semiconductor device structure. A ruthenium pattern film can be produced by plasma etching using a mixed gas containing an oxygen gas and a halogen gas. At this time, in an etching step in a vertical direction, there is a problem that bowing occurs due to side etching as illustrated in FIG. 1A, and an ideal pattern with a vertical side wall as illustrated in FIG. 1B cannot be formed. Here, In FIGS. 1A and 1B, FIG. 1A is a diagram illustrating the bowing formed by pattern etching, and FIG. 1B is a diagram illustrating the ideal vertical pattern. In addition, in FIGS. 1A and 1B, reference numeral 30 denotes a pattern mask, reference numeral 31 denotes a ruthenium pattern film, reference numeral 32 denotes a base film, and reference numeral 33 denotes ions.

PTL 1 discloses an etching method of alternately repeating plasma processing using an oxygen-containing gas and plasma processing using a chlorine-containing gas for a purpose of reducing in-surface variation of an etching rate of ruthenium.

In PTL 2, as illustrated in FIG. 2, a side wall protective film 41 is formed by irradiating a ruthenium pattern film 31 with a precursor gas derived from an oxide, a nitride, or a metal different from ruthenium such as tungsten. Then, a technique of forming the ruthenium pattern film 31 while reducing side etching by performing plasma etching using a mixed gas of oxygen and chlorine is disclosed.

### CITATION LIST

### Patent Literature

PTL 1: JP2019-169627A
PTL 2: JP2019-186322A

### SUMMARY OF INVENTION

### Technical Problem

As described above, in order to reduce side etching, a technique of etching while protecting a side wall of a ruthenium pattern is important.

PTL 1 discloses the etching method of reducing in-surface variation of an etching rate of a ruthenium flat film by alternately repeating the plasma processing using the oxygen-containing gas and the plasma processing using the chlorine-containing gas. In the method, a uniform oxide film is formed in a wafer surface by reacting plasma using the oxygen-containing gas with a surface of ruthenium to form a nonvolatile ruthenium dioxide (RuO₂), and then the chlorine-containing gas is reacted with a surface of the ruthenium dioxide to generate volatile ruthenium chloride, thereby performing etching. Therefore, when the ruthenium pattern is processed using the method, since the etching progresses by the reaction of the plasma using the chlorine-containing gas with the oxidized ruthenium dioxide also in the side wall, side etching of a ruthenium pattern film cannot be reduced, and the method cannot be applied to a pattern forming step,

In PTL 2, a method of achieving pattern etching by using the method disclosed in PTL 1 and a protective film forming step using a precursor gas in combination is disclosed. In the method disclosed in PTL 2, in order to introduce the protective film forming step by the precursor gas and a side wall protective film removing step, it is necessary to irradiate the ruthenium pattern film with a gas other than the oxygen gas or the halogen gas used for the ruthenium etching. In addition, in a plasma processing step using the oxygen-containing gas to be performed after the side wall protective film is formed, ruthenium is etched by reacting chlorine saturated and adsorbed to the surface of ruthenium and oxygen emitted from the plasma with the ruthenium. Then, in a plasma processing step using the chlorine-containing gas, ruthenium is etched by reacting oxygen saturated and adsorbed to the surface of ruthenium and chlorine emitted from the plasma with the ruthenium. Therefore, as a protective film for protecting the side wall, it is necessary to form a substance containing an element other than ruthenium on the side wall of the pattern.

However, the side wall protective film that has not been completely removed in the protective film removing step becomes a factor of contaminating a surface of the ruthenium pattern. Considering that ruthenium is applied as a wiring metal of a miniaturized semiconductor device and conductivity thereof is important, it is necessary to avoid impurity contamination on the surface of the ruthenium pattern.

The disclosure provides a technique capable of, by a simple process than methods in a related art, performing a step of forming and removing a side wall protective film while reducing impurity contamination on a surface of a pattern, and processing a ruthenium pattern into a desired cross-sectional shape with bowing or the like being reduced, Other technical problems and novel features will be apparent from description of the present specification and the accompanying drawings.

### Solution to Problem

Outlines of a representative one of the disclosure will be briefly described as follows.

According to an aspect of the disclosure,
a technique of a plasma processing method for etching a ruthenium film by plasma is provided, the method includes:
a first step of etching the ruthenium film by plasma generated using a mixed gas of an oxygen gas and a halogen gas;
a second step of forming a ruthenium compound on a side wall of the etched ruthenium film by radicals generated by plasma generated using the halogen gas, after the first step;
a third step of etching the ruthenium film by the plasma generated using the mixed gas of the oxygen gas and the halogen gas, after the second step; and
a fourth step of etching the side wall of the etched ruthenium film by oxygen radicals and halogen radicals generated by the plasma generated using the mixed gas of the oxygen gas and the halogen gas, after the third step, and
the second step to the fourth step are repeated until a depth of the etched ruthenium film reaches a predetermined depth.

### Advantageous Effects of Invention

According to the plasma processing method according to the disclosure, it is possible to, by a simple process, perform a step of forming and removing a side wall protective film while reducing impurity contamination on a surface of a pattern, and process a ruthenium pattern into a desired cross-sectional shape with bowing or the like being reduced. Specifically, formation of a side wall protective film derived from a nonvolatile ruthenium compound using a halogen gas (second step), vertical processing (third step), and pattern shape control (fourth step) are performed in a cycle step. As a result, a vertical ruthenium pattern whose pattern dimension is precisely controlled can be produced with high throughput while reducing impurity contamination on the surface.

### BRIEF DESCRIPTION OF DRAWINGS

FIGS. 1A and 1B are diagrams illustrating bowing formed by pattern etching and an ideal vertical pattern, in which FIG. 1A is a diagram illustrating the bowing formed by the pattern etching, and FIG. 1B is a diagram illustrating the ideal vertical pattern.

FIG. 2 is a diagram illustrating a problem of a protective film formed by a method in the related art,

FIG. 3 is a process flow diagram of an etching method of a ruthenium pattern according to the present embodiment.

FIG. 4 is a pattern cross-sectional view illustrating an example of a process flow of a method for etching ruthenium according to the present embodiment.

FIG. 5 is a diagram illustrating an example of an internal structure of a plasma processing device according to the present embodiment.

FIGS. 6A and 6B are diagrams illustrating another example of the internal structure of the plasma processing device according to the present embodiment, in which FIG. 6A is a diagram illustrating a case where an ECR surface is located on a lower side with respect to an ion shielding plate, and FIG. 6B is a diagram illustrating a case where the ECR surface is located on an upper side with respect to the ion shielding plate.

FIG. 7 is a diagram illustrating gas mixing ratio dependency of an etching rate of a ruthenium film when being etched with plasma using a mixed gas of oxygen and chlorine.

FIG. 8 is a diagram illustrating temperature dependency of an etching rate when the ruthenium film is irradiated with radicals contained in plasma using a mixed gas containing 90% oxygen and 10% chlorine.

FIG. 9 is a process flow diagram of another example of etching the ruthenium pattern according to the present embodiment.

FIG. 10 is a diagram illustrating a table in which an example of a ruthenium compound that is expected to be generated by ruthenium etching and a melting point and a boiling point of the ruthenium compound are clearly specified.

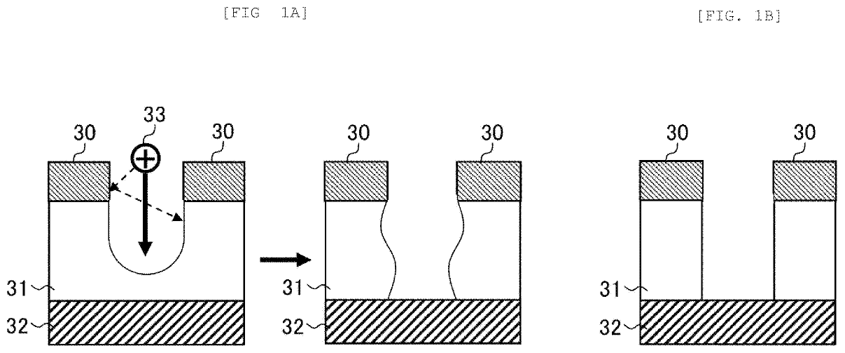

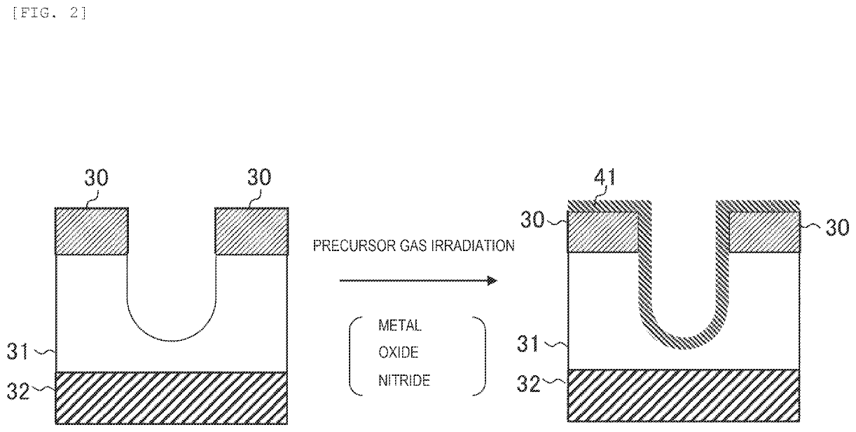

### DESCRIPTION OF EMBODIMENTS

Hereinafter, an embodiment of the present invention will be described in detail with reference to the drawings. In all the drawings, components having the same function are denoted by the same reference numerals, and repeated description thereof may be omitted. In order to make the description clearer, the drawings may be schematically illustrated in comparison with an actual aspect, but they are merely examples and do not limit the interpretation of the disclosure.

### Embodiment

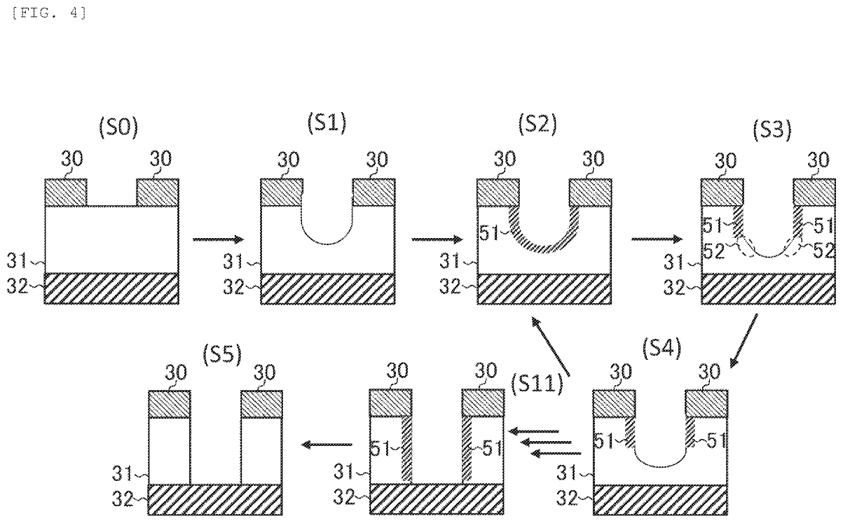

FIG. 3 is a process flow diagram of an etching method of a ruthenium pattern according to the present embodiment, FIG. 4 is a pattern cross-sectional view illustrating an example of a process flow of a method for etching ruthenium according to the present embodiment. FIG. 3 is a flowchart illustrating a processing method according to an embodiment, and FIG. 4 illustrates a structure of a pattern in each step.

The following example describes an etching method when chlorine is used as a halogen gas. Ruthenium 31 is formed on a base film 32 made of silicon or the like, and a region other than a pattern groove forming portion is covered with a mask 30. As a material for the mask 30, for example, silicon oxide, silicon nitride, titanium nitride, or the like having a low etching selectivity with respect to the ruthenium 31 can be used.

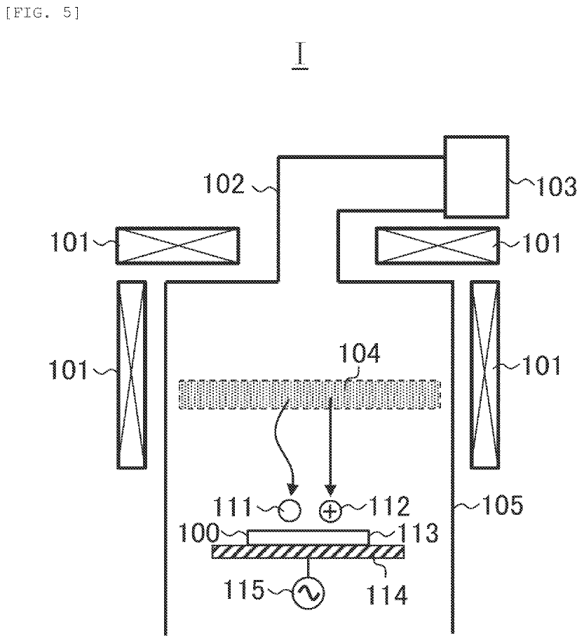

FIG. 5 is a diagram illustrating an example of an internal structure of a plasma processing device according to the present embodiment. Etching n the present embodiment can be performed by, for example, a microwave-electron cyclotron resonance plasma etcher (M-ECR) device as the plasma processing device. FIG. 5 illustrates a configuration diagram of the M-ECR device (hereinafter referred to as a device I). Inside a housing 105 of the device I, an electromagnetic coil 101 for generating plasma, a microwave source 103, and a circular waveguide 102 are installed. Plasma 104 generated from an etchant gas contains radicals 111 and ions 112, and the radicals 111 and the ions 112 are emitted onto a ruthenium film 113 formed on a main surface (surface) of a semiconductor wafer (also referred to as a substrate) as a sample 100 placed on a temperature adjustment stage 114 serving as a sample stage, A bias power supply 115 is connected to the stage 114, and incident energy of the ions 112 used for the etching can be adjusted by controlling an applied bias.

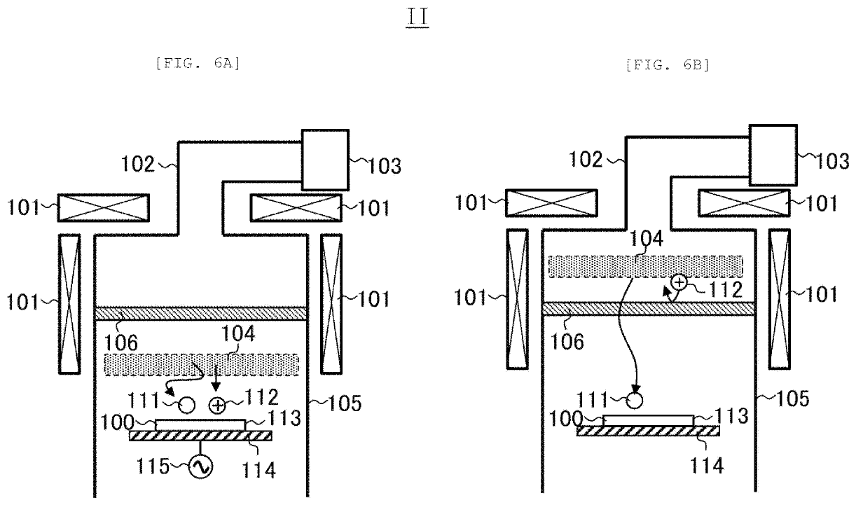

FIGS. 6A and 6B are diagrams illustrating another example of the internal structure of the plasma processing device according to the present embodiment, in which FIG. 6A is a diagram illustrating a case where an ECR surface is located on a lower side with respect to an ion shielding plate, and FIG. 6B is a diagram illustrating a case where the ECR surface is located on an upper side with respect to the ion shielding plate, FIGS. 6A and 6B illustrate a configuration diagram of another plasma processing device (hereinafter referred to as a device II). In the device II, as an example, in addition to the M-ECR device I in FIG. 5, an ion shielding plate 106 is installed inside the housing 105. The ion shielding plate 106 has a characteristic of allowing the radicals 111 in the plasma (ECR surface) 104 to pass through and not allowing the ions 112 to pass through. Therefore, in the case where the ECR surface 104 is located on the lower side with respect to the ion shielding plate 106 (FIG. 6A), as in the case of the device I, a plasma gas containing the radicals 111 and the ions 112 is emitted onto the ruthenium film 113 formed on the main surface (surface) of the substrate 100. On the other hand, in the case where the ECR surface 104 is located on the upper side with respect to the ion shielding plate 106 (FIG. 6B), plasma containing a large amount of radicals 111 passing through the ion shielding plate 106 is emitted onto the ruthenium film 113 formed on the main surface (surface) of the substrate 100. That is, by controlling a height of a generation region of the plasma 104, a mode (first etching mode: plasma irradiation) in which the radicals 111 and the ions 112 contained in the plasma 104 are anisotropically emitted and a mode (second etching mode: radical irradiation) in which the radicals 111 are isotropically emitted can be easily switched in the same chamber.

Since steps of the present embodiment include a pattern forming step (S1 and S3) by anisotropic etching, a step (S2) of isotropically forming a protective film on a surface of the pattern, and a step (S4) of controlling a pattern dimension, when the device II is used, these steps can be performed in the same chamber.

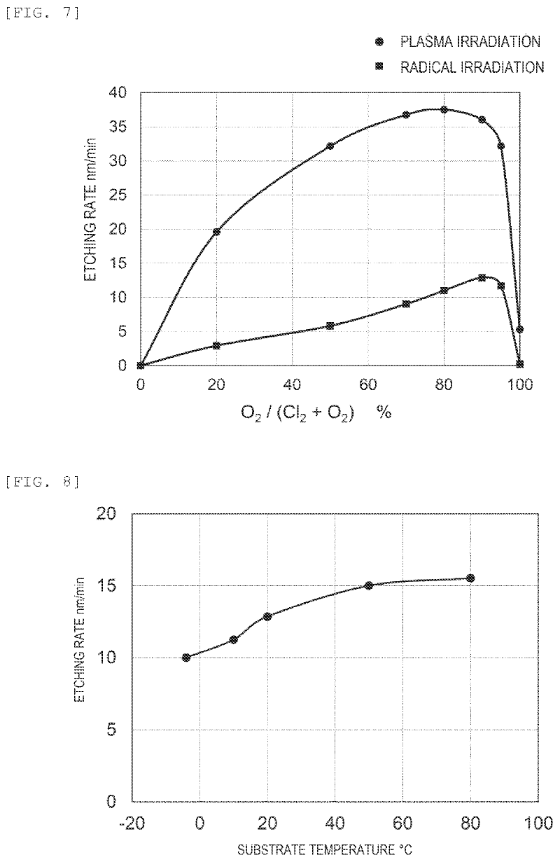

FIG. 7 is a diagram illustrating gas mixing ratio dependency of an etching rate of a ruthenium film when being etched with plasma using a mixed gas of oxygen and chlorine. A vertical axis represents the etching rate (nm/min), and a horizontal axis represents a gas mixing ratio (O2/(C12+O2)) % of the mixed gas of oxygen and chlorine. In addition, in FIG. 7, black circles indicate plasma irradiation (first etching mode), and black squares indicate radical irradiation (second etching mode).

When the ruthenium film 31 is etched in each etching mode (first etching mode or second etching mode) using the device II described above, a relationship between flow ratios of oxygen and chlorine and the etching rate is as illustrated in FIG. 7. In any of the etching modes, it can be confirmed that the etching rate of the ruthenium film 31 becomes maximum by adding a small amount (10% to 20%) of chlorine. In general, dry etching proceeds as a material to be etched changes to a volatile compound having a low boiling point by a chemical reaction.

Table 1 (TAB1) illustrated in FIG. 10 illustrates an example of a ruthenium compound generated by a chemical reaction of a plasma gas containing oxygen and chlorine with ruthenium, and a melting point (C) and a boiling point (C) of the ruthenium compound.

Ruthenium dioxide (RuO₂) has a melting point of 1300° C. or more, is nonvolatile, and is expected to be formed as an intermediate of an etching reaction. Rudy formed by further oxidation has a low boiling point and is volatile. That is, as a result of an increase in an oxidation reaction rate of ruthenium due to chlorine being added in a small amount and formation of a volatile ruthenium compound such as RuO₄ and ruthenium chloride (RuClₓO_{y}), the etching is expected to proceed. In addition, according to a paper of a research group of Graves (J. Vac. Sci. Technol. A, 2006, Vol. 24, pp. 1-8), since a plasma gas generated from a mixed gas containing 10% to 20% chlorine contains a large amount of ClO radicals, Cl₂⁺, and ClO₂⁺ ions, these chemical species are considered to promote the oxidation reaction of ruthenium.

On the other hand, it can be confirmed from FIG. 7 that when the flow ratio of chlorine increases from 20%, the etching rate of ruthenium decreases, and when a flow ratio of a chlorine gas is 100%, the etching hardly proceeds. When a surface of ruthenium is irradiated with chlorine plasma, it is expected that nonvolatile ruthenium chloride (RuCl₃) having a melting point of 500° C. or more is generated. That is, when the surface of ruthenium is irradiated with a plasma gas containing a large amount of chlorine, it is considered that a nonvolatile deposition film is formed on the surface of ruthenium and the etching reaction of ruthenium is inhibited. In the present embodiment, the nonvolatile ruthenium film is used as a side wall protective film for pattern etching.

First, an example of a pattern etching method of ruthenium using the device II will be described (see FIGS. 3 and 4), In FIG. 4, S0, S1, S2, S3, S4, S11, S5, and S6 are cross-sectional views corresponding to each step (S0, S1, S2, S3, S4, S11, S5, S6) in FIG. 3.

In an initial step (S0), the pattern mask 30 is formed, That is, the ruthenium 31 is formed on the base film 32 made of silicon or the like, and a region other than the pattern groove forming portion is covered with the mask 30.

In a process of forming a pattern in a first step (S1: produce initial pattern), in order to etch the ruthenium pattern 31 in a vertical direction, it is desirable that a high bias is applied as a power value of the radio frequency power 115 supplied to the sample stage 114, and then the substrate of the sample 100 is irradiated with the plasma gas. In addition, from FIG. 5, in a mode in which plasma containing both radicals and ions is emitted, since the etching rate becomes maximum when the flow ratios of oxygen and chlorine in the mixed gas are 80% and 20%, the vertical etching of the ruthenium film 31 becomes possible when the mixed gas having flow ratios close to the flow ratios is used. Here, the etching in the first step (S1) needs to be stopped before bowing is formed. For an etching time, the applied bias, and a substrate temperature of the sample 100 in the first step (S1), it is desirable to use an optimum value derived in advance by a systematic experiment. That is, the first step (S1) is a step of etching the ruthenium film 31 by plasma generated using a mixed gas of an oxygen gas and a halogen gas. Here, the halogen gas is a chlorine gas, a hydrogen bromide gas, or a mixed gas of the chlorine gas and the hydrogen bromide gas.

In a second step (S2: form protective film), a mode is applied in which radicals contained in a plasma gas generated from a gas containing chlorine as a main component are isotropically emitted onto a side wall and a bottom of the ruthenium pattern 31, and a surface of the ruthenium pattern 31 is protected by a film (protective film) containing nonvolatile ruthenium chloride (RuCl₃) 51. Here, the protective film of ruthenium chloride 51, which is a ruthenium compound, needs to be formed thick enough to prevent the side wall from being etched. In order to control a film thickness of the ruthenium chloride 51, a chlorine flow, a pressure, and the substrate temperature may be adjusted. That is, the second step (S2) is a step of forming the ruthenium compound 51 on the side wall of the etched ruthenium film 31 by radicals generated by the plasma generated using the halogen gas after the first step (S1).

In a third step (S3: perform vertical etching), a mode is applied in which the plasma containing both the radicals and the ions is anisotropically emitted onto the ruthenium pattern 31, and etching is performed in the vertical direction. At this time, a bias of the radio frequency power 115 applied from the sample stage 114 to the substrate of the sample 100 is set to be large enough to pass through the ruthenium chloride 51 deposited on the bottom of the ruthenium pattern 31, and a mixed gas with the flow ratios of oxygen and chlorine of about 80% and 20% is used. That is, the power value of the radio frequency power 115 applied from the sample stage 114 to the substrate of the sample 100 is set to a power value necessary for etching the ruthenium compound 51 formed on a bottom surface of the etched ruthenium 31. As a result, the protective film of ruthenium chloride 51 deposited on the bottom of the ruthenium pattern 31 can be efficiently removed, and ruthenium on the bottom is exposed to the surface. That is, the third step (S3) is a step of etching the ruthenium film 31 by the plasma generated using the mixed gas of the oxygen gas and the halogen gas after the second step (S2), Here, in the third step (S3), the radio frequency power 115 supplied to the sample stage 114 on which the sample 100 formed with the ruthenium film 31 is placed is the radio frequency power 115 having the power value necessary for etching the ruthenium compound 51 formed on the bottom surface of the etched ruthenium 31. The third step (33) is performed within a time and within a range of the radio frequency power 115 such that the protective film formed on the side wall in the second step is not removed.

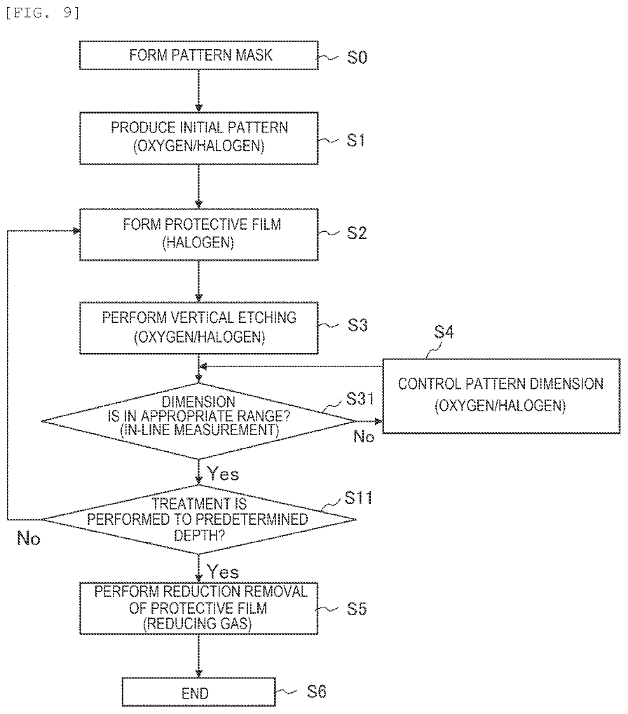

In a fourth step (S4: control pattern dimension), a mode is applied in which radicals contained in a plasma gas generated from the mixed gas containing oxygen and chlorine are isotropically emitted, and the pattern dimension is adjusted by etching such that ruthenium 52 (refer to S3 in FIG. 4) on the side wall of the pattern that is not protected by the ruthenium chloride 51 is vertical. From FIG. 7, since the etching rate becomes maximum when the flow ratios of oxygen and chlorine in the mixed gas are 90% and 10% at the time of the etching by the radicals, it is desirable to etch under a similar condition. In addition, temperature dependency of the etching rate at this flow ratio is illustrated in FIG. 8. FIG. 8 illustrates temperature dependency of an etching rate when the ruthenium film is irradiated with radicals contained in plasma using the mixed gas containing 90% oxygen and 10% chlorine. A vertical axis represents the etching rate (nm/min), and a horizontal axis represents the substrate temperature (C). As can be seen from FIG. 8, in the ruthenium etching with the radicals, the etching rate increases as the substrate temperature of the sample 100 increases. Therefore, by controlling in-surface temperature distribution of the stage 114, it is possible to eliminate variation in the pattern dimension of a wafer surface, which is the sample 100, and to process the pattern with a uniform dimension. That is, the fourth step (S4) is a step of etching the side wall of the etched ruthenium film 31 by oxygen radicals and halogen radicals generated by the plasma generated using the mixed gas of the oxygen gas and the halogen gas after the third step (S3). By the fourth step (S4), an etching condition is adjusted such that a dimension of an etching shape becomes a desired dimension. In addition, in the fourth step (S4), temperature distribution in a surface of the sample 100 is adjusted such that the etching rate in the surface of the sample 100 on which the ruthenium film 31 is formed and the dimension of the etching shape in the surface of the sample 100 become uniform.

A part of the ruthenium pattern 31 formed after the fourth step (S4) includes a region that is not protected by the ruthenium chloride 51. Therefore, by performing the second step (S2) again, the surface of the ruthenium pattern 31 is entirely protected by the ruthenium chloride 51. In this way, the second step (S2), the third step (S3), and the fourth step (4) are repeated and then it is determined whether a predetermined depth is reached (S11: it is determined whether the processing is performed to a predetermined depth). When the predetermined depth is not reached (No), the process proceeds to the second step (S2). When the predetermined depth is reached (Yes), the etching is ended, and the process proceeds to a fifth step (S5; perform reduction removal of the protective film).

Here, the ruthenium chloride 51 that covers the side wall of the pattern may lower conductivity of the ruthenium pattern 31. Therefore, in the fifth step (S5), reductive radicals are emitted for a purpose of reducing the ruthenium chloride 51 on the surface of the ruthenium pattern 31 to metal ruthenium. For example, since a reaction of RuCl₃+3H⁺→Ru+3HCl occurs when hydrogen radicals (H⁺) contained in plasma generated from a gas containing the hydrogen gas are emitted to the ruthenium chloride, the ruthenium chloride 51 on the surface of the pattern can be reduced to metal ruthenium. That is, the fifth step (S5) is a step of reducing the ruthenium compound 51 to metal ruthenium after the fourth step (S4). When the fifth step (S5) is ended, the pattern etching of ruthenium is ended (S6).

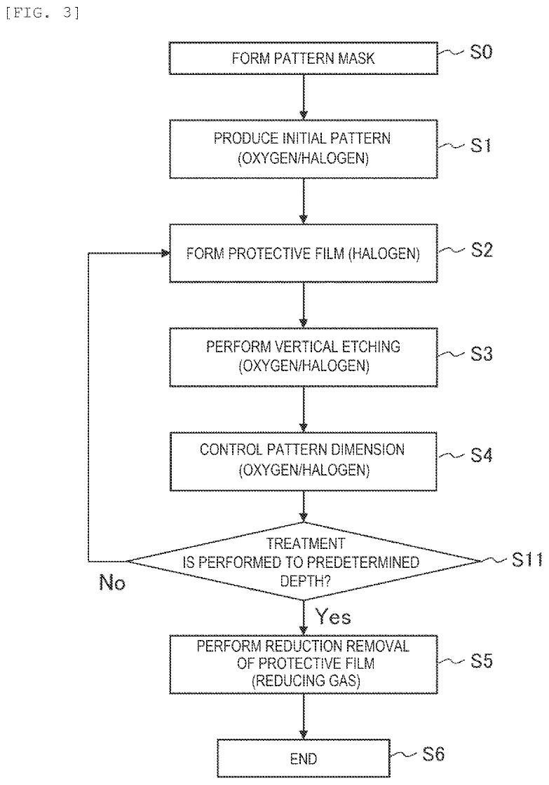

Advantages of the present embodiment are in the second step (32) of forming the protective film (51). In the related art illustrated in FIG. 2, a protective film 41 derived from an element (tungsten, silicon, titanium, or the like) other than ruthenium is formed. However, in the related art illustrated in FIG. 2, since a precursor gas irradiation step of forming the side wall protective film and a protective film removing step are incorporated, the process is complicated. In addition, residues of the protective film 41 may contaminate the surface of the pattern.

In the present embodiment, the side wall can be protected by modifying the surface of the ruthenium pattern 31 into the nonvolatile ruthenium compound 51. In addition, by irradiating the protective film (51) with a reducing gas such as hydrogen plasma, the protective film (51) can be easily reduced to metal ruthenium. By applying the process of the present embodiment, it is possible to produce, by a simpler etching process than in the related art, a ruthenium pattern in which a cross-sectional shape and the dimension are precisely controlled while preventing impurity contamination on the surface of ruthenium.

Next, an example of an etching method when the device I is applied will be described (see FIGS. 3 and 4).

In the first step (S1) of forming the initial pattern, a high bias is applied to the ruthenium pattern 31 as the power value of the radio frequency power 115 in order to etch in the vertical direction.

In the second step (S2) of protecting the side wall, in order to form the ruthenium chloride 51 not only on the bottom but also on the side wall of the ruthenium pattern 31, an applied voltage, which is the power value of the radio frequency power 115 for the substrate of the sample 100, is set to 0 or a low bias.

In the third step (S3) of vertically etching the pattern, a high bias is applied to the substrate so as to pass through the ruthenium chloride 51 at the bottom of the ruthenium pattern 31.

In the fourth step (S4) of adjusting the pattern dimension, since it is necessary to etch the ruthenium 52 of the side wall of the pattern that is not protected by ruthenium chloride, the applied voltage for the substrate is set to 0 or a low bias.

In the fifth step (S5) of reducing the ruthenium chloride 51 to metal ruthenium, since the reducing radicals are isotropically emitted onto the entire surface including the side wall, the applied voltage, which is the power value of the radio frequency power 115, is set to 0 or a low bias.

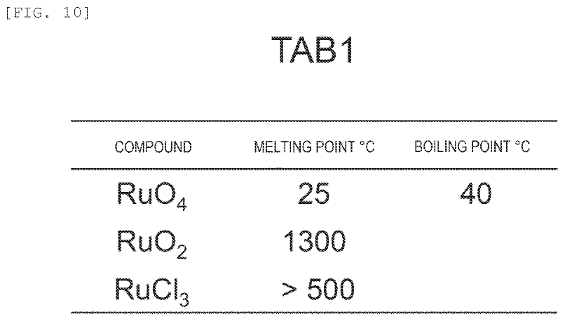

In the example of the etching method described above, an optical pattern shape measuring device may be installed to measure the pattern dimension of the ruthenium pattern 31, and a step of appropriately determining whether the pattern dimension, the film thickness, and other pattern shapes are appropriate values (S31: refer to FIG. 9) may be introduced. FIG. 9 is a process flow diagram of another example of etching the ruthenium pattern according to the present embodiment. FIG. 9 illustrates an example of a process flow to which a measurement method (S31) is applied. In FIG. 9, the same steps as those in FIG. 7 are denoted by the same reference numerals, and repetitive description thereof will be omitted.

As in FIG. 7, after the initial step (S0), the first step (S1), the second step (S2), and the third step (S3) are applied, the pattern dimension of the ruthenium pattern 31 is measured using an in-line spectrometer (S31), When the pattern dimension does not reach the appropriate value (No), the pattern dimension is controlled by etching using the mixed gas containing oxygen and chlorine (S4). When the in-line spectrometry (S31) and the pattern dimension control step (84) are repeated and the pattern dimension reaches the appropriate range (Yes), the process proceeds to a next step (S11). Thereafter, as d described with reference to FIG. 7, the fifth step (S5) and the end step (S6) are performed.

By applying the above process flow, it is possible to appropriately correct the pattern dimension in each cycle etching step, and thus it is possible to provide a side wall having high surface flatness of the pattern.

Although the chlorine gas is used as the halogen gas in the present embodiment, a fluorocarbon gas such as a hydrogen bromide gas (HBr), a nitrogen trifluoride gas (NF₃), a sulfur hexafluoride gas (SF₆), tetrafluoromethane (CF₄), and methane trifluoride (CHF₃), or a hydrofluorocarbon gas may also be used as the halogen gas in the invention.

In the present embodiment, the case where a shape perpendicular to the substrate of the sample 100 is mainly processed as the pattern shape is described in the present embodiment, and it is also possible to form a reversed tapered pattern. In this case, the protective film is formed on an upper portion of the pattern in the second step (S2), and after the third step (S3) of etching the pattern is performed, in the fourth step (S4) of adjusting the pattern dimension, a lower portion of the pattern is etched in a lateral direction without etching the upper portion of the pattern by performing the etching in the lateral direction of the pattern.

Although the case of etching the ruthenium pattern is described as an example in the present embodiment, the pattern can be processed by performing the side wall protection of the pattern with a metal material such as molybdenum by using the same method.

While the disclosure made by the inventor has been described in detail based on the embodiment, the disclosure is not limited to the above-described embodiment, and various modifications can be made without departing from the scope of the disclosure. For example, the embodiment described above has been described in detail for easy understanding of the invention, and is not necessarily limited to those having all the described configurations.

In addition, a part of the configuration of each embodiment may be added, deleted, replaced with another configuration.

### REFERENCE SIGNS LIST

30: pattern mask
31: ruthenium pattern film
32: base film
33: ion
41: protective film formed of precursor gas
51: protective film formed of nonvolatile ruthenium compound
52: ruthenium on side wall of pattern not protected by nonvolatile ruthenium compound
101: electromagnetic coil
102: circular waveguide
103: microwave source
104: ECR surface
105: inner tube
106: ion shielding plate
111: radicals
112: ions
113: substrate
114: temperature adjustment stage
115: bias power supply

1. A plasma processing method for etching a ruthenium film by plasma, the plasma processing method comprising:
a first step of etching the ruthenium film by plasma generated using a mixed gas of an oxygen gas and a halogen gas;
a second step of forming a ruthenium compound on a side wall of the etched ruthenium film by radicals generated by plasma generated using the halogen gas, after the first step;
a third step of etching the ruthenium film by the plasma generated using the mixed gas of the oxygen gas and the halogen gas, after the second step; and
a fourth step of etching the side wall of the etched ruthenium film by oxygen radicals and halogen radicals generated by the plasma generated using the mixed gas of the oxygen gas and the halogen gas, after the third step, wherein
the second step to the fourth step are repeated until a depth of the etched ruthenium film reaches a predetermined depth.

2. The plasma processing method according to claim 1, further comprising:
a fifth step of reducing the ruthenium compound to metal ruthenium, after the fourth step.

3. The plasma processing method according to claim 1, wherein
the halogen gas is a chlorine gas, a hydrogen bromide gas, or a mixed gas of the chlorine gas and the hydrogen bromide gas.

4. The plasma processing method according to claim 1, wherein
in the third step, radio frequency power supplied to a sample stage on which a sample formed with the ruthenium film is placed is radio frequency power having a power value necessary for etching a ruthenium compound formed on a bottom surface of the etched ruthenium.

5. The plasma processing method according to claim 1, wherein
in the fourth step, an etching condition is adjusted such that a dimension of an etching shape becomes a desired dimension.

6. The plasma processing method according to claim 1, wherein
in the fourth step, temperature distribution in a surface of a sample on which the ruthenium film is formed is adjusted such that an etching rate in the surface of the sample and a dimension of an etching shape in the surface of the sample become uniform.
